(19) United States
(12) Patent Application Publication
(10) Pub. No.: US 2026/0036916 A1
(43) Pub. Date: Feb. 5, 2026

(54) ANALYSIS APPARATUS

(71) Applicant: SAMSUNG ELECTRONICS CO., LTD., Suwon-si (KR)

(72) Inventors: Junho Shin, Suwon-si (KR); Jangwoon Sung, Suwon-si (KR); Wookrae Kim, Suwon-si (KR); Seungbeom Park, Suwon-si (KR); Sangwoo Bae, Suwon-si (KR); Myungjun Lee, Suwon-si (KR)

(21) Appl. No.: 19/022,982

(22) Filed: Jan. 15, 2025

(30) Foreign Application Priority Data
Aug. 1, 2024 (KR) 10-2024-0102296

(51) Int. Cl. G03F 7/00; G01N 23/2055

(52) U.S. Cl. CPC G03F 7/707; G01N 23/2055; G03F 7/70025; G03F 7/70716

(57) ABSTRACT

Systems, devices, and operation methods for an analysis apparatus are provided. In one aspect, an analysis apparatus includes a stage having a rotating chuck configured to rotate around an axis of rotation, one or more light sources configured to irradiate light onto a first region of a substrate disposed on the stage, one or more sensors configured to sense diffraction patterns that respectively correspond to a plurality of rotation angles from a rotation of the rotating chuck, and a processor configured to reconstruct data of the first region using the diffraction patterns respectively corresponding to the plurality of rotation angles, where the diffraction pattern is based on scattering of the light irradiated onto the first region.

### CROSS-REFERENCE TO RELATED APPLICATION

This application claims priority under 35 U.S.C. § 119 to Korean Patent Application No. 10-2024-0102296, filed in the Korean Intellectual Property Office on Aug. 1, 2024, the entire contents of which are hereby incorporated by reference.

### BACKGROUND

For the analysis or measurement of a material of an arbitrary three-dimensional (3D) structure or for the verification of errors in mass-produced samples, the information may be obtained on the structure of the material or the samples or image the same.

In related art, a surface structure or 3D structure of a sample may be analyzed with an interferometer that uses visible light. However, the visible light interferometer may have low absorption rates for transparent thin films compared to light with shorter wavelengths, resulting in overlapping images of the surface structure or the 3D structure and internal structures of the sample.

### SUMMARY

In order to solve one or more problems (e.g., the problems described above and/or other problems not explicitly described herein), the present disclosure provides an apparatus for analyzing physical, electrical, and chemical characteristics of a sample having a 3D structure. In additional, or alternatively, the apparatus can be capable of imaging a 3D structure with high resolution.

According to some implementations of the present disclosure, an analysis apparatus may include a stage including a rotating chuck rotated around an axis of rotation, one or more light sources configured to irradiate light onto a first region of a substrate disposed on the stage, one or more sensors configured to sense diffraction patterns respectively corresponding to a plurality of rotation angles based on a rotation of the rotating chuck, the diffraction patterns being generated based on scattering of the light irradiated onto the first region of the substrate; and a processor configured to reconstruct data of the first region using the diffraction patterns.

According to some implementations, the analysis apparatus may include a stage including a rotating chuck configured to be rotated around an axis of rotation; one or more light sources configured to irradiate light onto a first region of a substrate disposed on the stage; one or more sensors configured to sense diffraction patterns that respectively correspond to a plurality of rotation angles based on a rotation of the rotating chuck, the diffraction patterns being generated based on scattering of the light irradiated onto the first region of the substrate; one or more optical elements configured to steer a portion of a diffracted light scattered from the first region toward the one or more sensors; and a processor configured to reconstruct data of the first region using the diffraction patterns.

According to some implementations, the analysis apparatus may a stage that includes a rotating chuck configured to be rotated around an axis of rotation and a moving chuck configured to translate a substrate disposed on the rotating chuck in a direction perpendicular to the axis of rotation; one or more light sources configured to irradiate light onto a first region of the substrate; one or more sensors configured to sense diffraction patterns that respectively correspond to a plurality of rotation angles based on a rotation of the rotating chuck, the diffraction patterns being generated based on scattering of the light irradiated onto the first region of the substrate; one or more diffraction gratings configured to steer at least one portion of a diffracted light scattered from the first region toward the one or more sensors; and a processor configured to reconstruct data of the first region using the diffraction patterns, where the one or more diffraction gratings comprise a first grating pattern configured to steer a first portion of the at least one portion of the diffracted light to a first direction and a second grating pattern configured to steer a second portion of the at least one portion of the diffracted light to a second direction different from the first direction, and the first portion of the at least one portion of the diffracted light steered at the first grating pattern and the second portion of the at least one portion of the diffracted light steered at the second grating pattern are received at different positions of at least one of the one or more sensors.

According to some implementations of the present disclosure, it is possible to provide an analysis apparatus that more precisely measures physical, electrical, and/or chemical characteristics of a sample.

According to some implementations, it is possible to provide an analysis apparatus capable of improving a measurement range of the light scattered by the substrate.

According to some implementations, it is possible to provide an analysis apparatus capable of increasing the output when the light is reflected or scattered from the substrate, and also generating a high-resolution image.

According to some implementations, it is possible to provide an analysis apparatus with high performance of analyzing, measuring, and/or detecting fine defects of a sample.

### BRIEF DESCRIPTION OF THE DRAWINGS

The above and other objects, features and advantages of the present disclosure will become more apparent to those of ordinary skill in the art by describing in detail example implementations thereof with reference to the accompanying drawings, in which:

FIG. 1 is a diagram schematically illustrating a lithographic apparatus;

FIG. 2 is a diagram illustrating an example analysis apparatus;

FIG. 3A is an example perspective view illustrating some of light components sensed by a sensor at a first rotation angle;

FIG. 3B is an example perspective view illustrating some of light components sensed by a sensor at a second rotation angle;

FIG. 4 shows a plan view illustrating a part of an example process of rotating a stage of an analysis apparatus and corresponding diffraction pattern measurement data sensed by a sensor;

FIG. 5A shows a graph representing an example light receiving region when a stage of an analysis apparatus remains static;

FIG. 5B shows graphs representing light components of an example diffracted light at various angles from a rotation of a stage of an analysis apparatus;

FIG. 5C is a diagram schematically illustrating example light receiving regions when a stage of an analysis apparatus is rotated;

FIG. 6A shows an example simulation result of sensing a diffraction pattern of a region of a substrate that is not being rotated;

FIG. 6B shows an example simulation result showing a resultant diffraction pattern obtained by synthesis and reconstruction from diffraction patterns corresponding to a plurality of angles obtained while rotating a region of the substrate;

FIG. 7 is a conceptual diagram illustrating several example regions on the substrate where light is irradiated;

FIG. 8 is a diagram illustrating another example analysis apparatus;

FIG. 9 is a conceptual diagram illustrating an example sensor and an example optical element in the analysis apparatus of FIG. 8;

FIG. 10 is a diagram schematically illustrating a diffraction pattern disposed on the example optical element of FIG. 9;

FIG. 11 is a graph illustrating an example light receiving region using the analysis apparatus of FIG. 8;

FIG. 12 shows a simulation result showing an example diffraction pattern using the analysis apparatus of FIG. 8;

FIG. 13 is a perspective view of yet another example analysis apparatus;

FIG. 14 is a perspective view of still another example analysis apparatus;

FIG. 15 is a flowchart of an example process for operating an example analysis apparatus; and

FIG. 16 is a flowchart of an example process for sub-operations of a first operation of the example process of FIG. 15.

### DETAILED DESCRIPTION

A semiconductor package according to one or more implementations of the present disclosure will be described in detail with reference to the drawings.

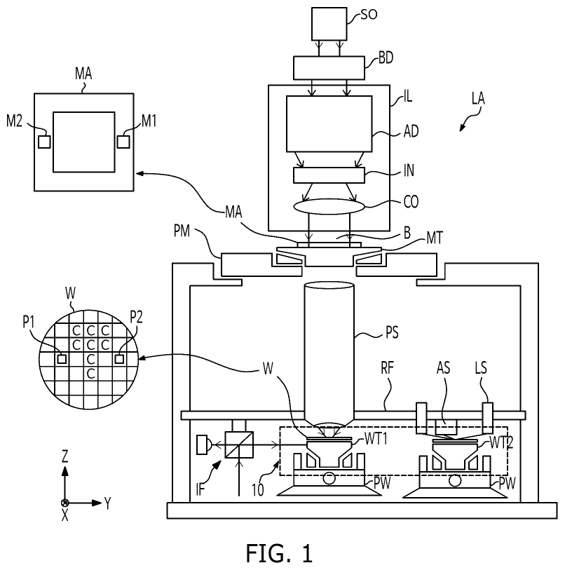

FIG. 1 is a diagram illustrating a lithographic apparatus according to one or more implementations.

Referring to FIG. 1, a lithographic apparatus LA may include a source SO, an illuminator IL, a patterning device MA, a first positioner PM, a mask table MT, a second positioner PW, wafer tables WT1 and WT2, and a projection system PS.

In the following description, two directions substantially parallel to an upper surface of a wafer W disposed inside the lithographic apparatus LA may be defined as a first direction (X direction) and a second direction (Y direction) which are substantially perpendicular to each other. In addition, a direction substantially perpendicular to the upper surface of the wafer may be defined as a third direction (Z direction).

For example, the source SO may emit a radiation beam B such as an ultraviolet ray, an excimer laser beam, an extreme ultraviolet (EUV) ray, an X ray, an electron ray, etc. In some cases, the source SO may be part of the components included in the lithographic apparatus LA or may be implemented as an independent separate device. For example, if the source is an excimer laser, the source SO may be a separate configuration from the lithographic apparatus LA. In this case, the radiation beam B may be transferred from the source SO to the illuminator IL by a beam transfer system BD including a beam expander. For example, if the source SO is a mercury lamp, the source SO may be included in the lithographic apparatus LA. The terms “radiation” and “beam” as used herein may encompass all types of electromagnetic radiation including ultraviolet (UV) ray (e.g., having a wavelength of about 365, 355,248, 193, 157 or 126 nm) and extreme ultraviolet (EUV) ray (e.g., having a wavelength in the range of 10 to 120 nm), as well as particle beams such as ion beams or electron beams.

The illuminator IL may receive the radiation beam B from the source SO. The illuminator IL may direct the radiation beam B to a set direction, or shape, or control the shape of, the radiation beam B. According to some implementations, the illuminator IL may include various types of optical components including refractive types, reflective types, magnetic types, electromagnetic types, electrostatic types, or a combination thereof.

The illuminator IL may include an adjuster AD, an integrator IN, and a condenser CO, which are configured to adjust the intensity distribution according to the angle of the radiation beam B. The adjuster AD may adjust an outer radius and/or inner radius size, etc. of the intensity distribution of a pupil plane of the illuminator IL. The illuminator IL may adjust the radiation beam B such that the cross section of the radiation beam B has a desired uniformity and intensity distribution.

The mask table MT may support the patterning device MA. The mask table MT may use various clamping techniques such as mechanical, vacuum, electrostatic clamping techniques or any combination thereof to hold the patterning device MA. In one example, the mask table MT may be a fixed frame or table. In another example, the mask table MT may be a movable frame or table. The mask table MT may position the patterning device MA at a position set for the projection system PS. The radiation beam B may be incident on the patterning device MA supported by the mask table MT. The cross section of the radiation beam B incident on the patterning device MA may be changed to a shape set by the patterning device MA. The projection system PS may include a refractive type, a reflective type, a catadioptric type, a magnetic type, an electromagnetic type, an electrostatic optical type, or a plurality of combinations of these.

According to some implementations, the patterning device MA may be transmissive or reflective. For example, the patterning device MA may be any one of a mask, a programmable mirror array, and programmable LCD panels. For example, if the patterning device MA is a mask type, the patterning device MA may be any one of a binary type, an alternating phase-shift type, a damping phase-shift type, or a variety of hybrid types, but is not limited thereto. For example, if the patterning device MA is a programmable mirror array, the patterning device MA may include a set of small mirrors arranged in the form of a matrix, for example. Each of the small mirror included in the patterning device MA may be individually inclined to reflect radiation beams incident on the small mirror in different directions. Each of the inclined small mirrors may form a pattern on the radiation beam B reflected by the mirror matrix.

The radiation beam B may pass through the projection system PS, and the projection system PS may focus the radiation beam B on a target portion C of the wafer W. The second positioner PW and the position sensor IF may drive the wafer table WT1 such that the radiation beam B is sequentially focused on the target portion C of the wafer W disposed on the wafer table WT1.

According to some implementations, in the lithographic apparatus LA, two wafer tables WT1 and WT2 may be exchanged. For example, while the wafer W on one wafer table WT1 is being exposed, the other wafer may be loaded on the other wafer table WT2 for wafer alignment, etc.

The second positioner PW may drive the wafer tables WT1 and WT2 to implement a designed circuit pattern. For example, the second positioner PW may drive the wafer tables WT1 and WT2 such that the radiation beam is focused at a set position on the wafer W. The set position on the wafer W may be defined from a model function calculated using wafer alignment marks P1 and P2. The model function is a function of positions identified by the wafer alignment marks P1 and P2, or a function of the identified position of any component on the wafer from the identified positions. In addition, the second positioner PW may drive the wafer table WT1 such that a layer formed on the wafer W by the lithography process is aligned with an underlying layer so that a normally operating semiconductor device is formed.

A reference frame RF may be connected to various components and may serve as a reference for setting and measuring positions of features on the patterning device MA and the wafer W. For example, if the position sensor IF fails to measure the positions of the wafer tables WT1 and WT2, the positions of the wafer tables WT1 and WT2 may be calculated based on the reference frame RF.

According to some implementations, a space between the projection system PS and the wafer W may be filled with a liquid having a high refractive index. In some cases, at least a portion of the wafer W may be covered by the liquid. The liquid is referred to herein as an immersion liquid, and the immersion liquid may fill other spaces in the lithographic apparatus, for example, a space between the patterning device MA and the projection system PS. In this case, immersion may not only refer to the wafer W being simply immersed in the liquid, but also to the immersion liquid being placed on a path of the radiation beam B for performing exposure.

The lithographic apparatus LA may include a scanner for aligning the wafer W placed on the wafer table WT2. The scanner may include an alignment sensor AS that detects the diffracted light for alignment in the first direction X and/or the second direction Y. In addition, the scanner may include a level sensor LS for alignment in the third direction Z.

The patterning device MA drawn from the mask library may be accurately moved by the first positioner PM and an additional position sensor to be positioned on the path of the radiation beam B during the exposure process.

According to some implementations, if the lithographic apparatus LA is operated in a stepper mode, the entire pattern set in the radiation beam B may be projected onto the target portion C at once while the mask table MT and the wafer table WT1 are maintained in a stopped state. The patterning device MA and the wafer W may be aligned by using mask alignment marks M1 and M2 formed on the patterning device MA and substrate alignment marks P1 and P2 formed on the wafer W. The wafer table WT1 may be moved in a horizontal direction with respect to the upper surface of the wafer W such that the other target portion C may be exposed. In the stepper mode, the maximum size of the exposure field may define the size of the target portion C imaged during exposure.

According to some implementations, if the lithographic apparatus LA is operated in a scan mode, the mask table MT and the wafer table WT1 may be synchronized and moved relative to each other while the radiation beam B is projected onto the target portion C. The speed and direction of the relative motion of the wafer table WT1 with respect to the mask table MT may be determined by the enlargement (or reduction) and image inversion characteristics of the projection system PS. In the scan mode, the maximum size of the exposure field may limit the horizontal width of the target portion C during exposure.

According to some implementations, a 3D pattern may be formed on the substrate by the lithography process of the lithographic apparatus LA. The substrate may be the wafer W. However, aspects are not limited thereto, and the substrate may be a semiconductor substrate, a glass substrate, etc. instead of the wafer W. In addition, the substrate is not limited to the semiconductor field, and may include a substrate of other fields, such as a display substrate. The lithographic apparatus LA may include an analysis apparatus 10 as part of its components to collect data on the 3D pattern formed on the substrate. However, aspects are not limited thereto, and the analysis apparatus 10 may be a separate device independent of the lithographic apparatus LA. Light emitted from the analysis apparatus 10 may be irradiated onto the wafer W of the substrate, and light scattered and diffracted from the substrate may be received by the analysis apparatus 10. The analysis apparatus 10 may sense the light diffracted from the substrate and measure the physical, electromagnetic, chemical, optical, or crystal structural characteristics of the substrate. For example, the analysis apparatus 10 may derive imaging of a 3D structure or pattern on the substrate formed by the lithography process. Meanwhile, aspects are not limited to the above, and the analysis apparatus 10 may also derive imaging of a 3D pattern of a substrate that is formed by another process that applies deformation to the substrate. In addition, without being limited to structural characteristics, the analysis apparatus 10 may measure various other characteristics using various data obtained from the sensed light. For example, if the analysis apparatus 10 applies voltage to the substrate or additionally irradiates the substrate with separate light to excite the material that forms the substrate and analyze the substrate, the analysis apparatus 10 may measure the electromagnetic characteristics, etc. of the substrate. In this case, the electromagnetic characteristics may refer to the electromagnetic characteristics according to each position on the substrate.

According to some implementations, the analysis apparatus 10 may analyze the characteristics of the substrate simultaneously while the lithographic apparatus LA is performing the process or after the process is completed. For example, if the characteristics of the substrate are analyzed by the analysis apparatus 10 after the process is completed, the analysis apparatus 10 may analyze the characteristics of the substrate positioned inside the lithographic apparatus LA or the substrate positioned outside of the lithographic apparatus LA.

According to some implementations, the characteristics of the substrate may be derived with the analysis apparatus 10 to detect errors in the process. However, the analysis apparatus 10 is not limited to the detection of the errors in the substrate generated by the process, and may be used for the analysis of the characteristics of a general sample. For example, after detecting errors from the characteristics of the substrate, the lithography process may be additionally performed or other processes may be added to ensure the substrate has the desired characteristics or to reduce errors in the process. In this case, the additional processes are not limited to the semiconductor field but may include processes from other technological fields. The analysis apparatus 10 may be positioned within the dashed-line rectangle illustrated in FIG. 1, but aspects are not limited thereto, and the analysis apparatus 10 may be disposed in various positions.

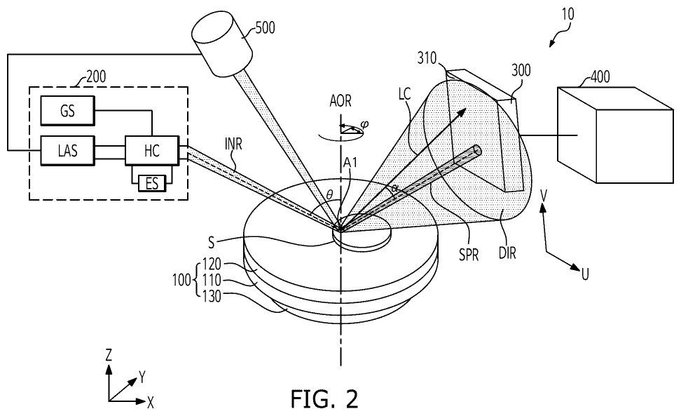

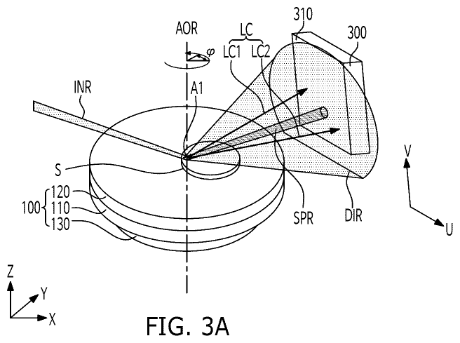

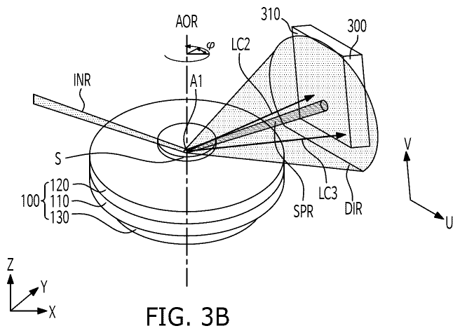

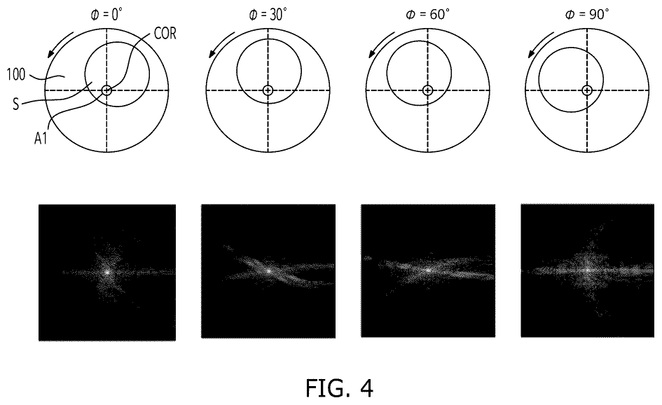

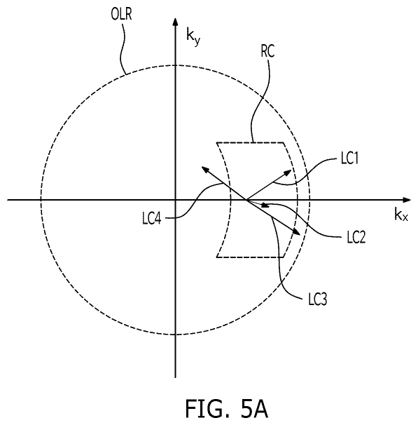

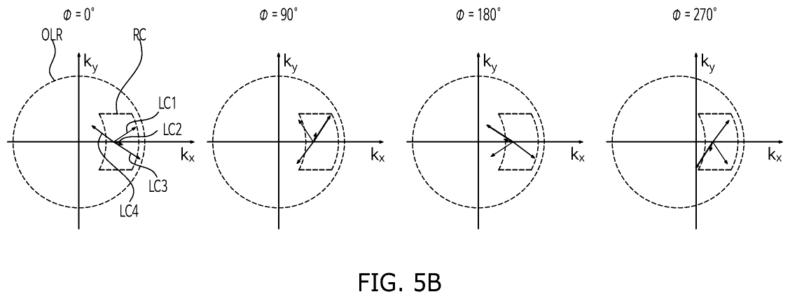

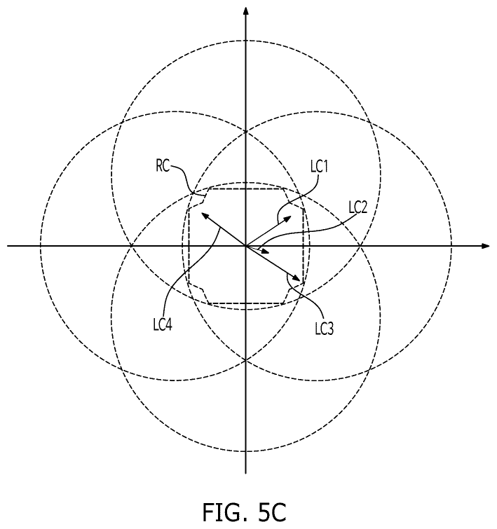

FIG. 2 is a diagram illustrating the analysis apparatus according to one or more implementations, FIG. 3A is a perspective view illustrating some of light components sensed by a sensor at a first rotation angle, and FIG. 3B is a perspective view illustrating some of light components sensed by the sensor at a second rotation angle. FIG. 4 shows a plan view illustrating a part of a process of rotating a stage of the analysis apparatus according to one or more implementations, and the corresponding diffraction pattern measurement data sensed by a sensor. FIG. 5A shows a graph representing a light receiving region that can be obtained when the stage of the analysis apparatus is fixed according to one or more implementations, FIG. 5B shows graphs representing light components of diffracted light appearing at certain angles according to the rotation of the stage of the analysis apparatus according to one or more implementations, and FIG. 5C is a diagram schematically illustrating light receiving regions that can be obtained when the stage of the analysis apparatus is rotated according to one or more implementations.

According to FIG. 2, the analysis apparatus 10 according to one or more implementations may include a stage 100 including a rotating chuck 110 rotated around a predetermined axis of rotation AOR, at least one light source 200 that irradiates light INR onto a first region A1 on a substrate S disposed on the stage 100, one or more sensors 300 that sense a diffraction pattern of diffracted light DIR formed after being scattered from the first region A1, and a processor 400 that reconstructs data of the first region A1 using the diffraction pattern. The data of the first region A1 can include, e.g., a three-dimensional (3D) or a two-dimensional (2D) structure profile, layout, density, or pattern in the first region A1. Alternatively, or additionally, the data of the first region A1 can include the physical, chemical, electromagnetic, optical, crystallographic characteristics of the first region A1, as described below in reference to a pumping element 500 of FIG. 2. As the rotating chuck 110 is rotated, the rotating chuck 110 is rotated by different rotation angles φ and at least one of the sensors 300 may sense a diffraction pattern for each of the rotation angles φ. In other words, the sensor 300 may sense the diffraction pattern corresponding to each of the plurality of rotation angles φ. The processor 400 may reconstruct the data of the first region A1 using the diffraction patterns respectively corresponding to the plurality of rotation angles φ. In this case, each of the plurality of sensed diffraction patterns matched with the rotation angle φ information may be processed in the processor 400. By obtaining a plurality of diffraction patterns while rotating each region of the substrate S around the axis of rotation AOR, it is possible to acquire diffracted light DIR components obscured by the sample and thereby provide an expanded light receiving region. In addition, by reconstructing the data with phase retrieval on diffraction patterns according to each rotation angle φ in a plurality of regions on the substrate S, a high-resolution image of a 3D structure or pattern of the substrate S may be acquired.

According to some implementations, the analysis apparatus 10 may include the stage 100. The stage 100 may include the rotating chuck 110 rotated around the predetermined axis of rotation AOR. The predetermined axis of rotation AOR may pass through an upper surface of the rotating chuck 110 and may be substantially perpendicular to the upper surface of the rotating chuck 110. The expression “the axis of rotation passes through the region” as used herein may mean that the axis of rotation as a straight line and the region as a plane meet at one point.

For example, the upper surface of the rotating chuck 110 may be parallel to the first and second directions which are perpendicular to each other, and the axis of rotation AOR may be perpendicular to both the first and second directions. For example, the first and second directions may be the X and Y directions, respectively, and the axis of rotation AOR may be the Z direction. For example, if the upper surface of the rotating chuck 110 has a circular shape, a regular polygonal shape, or a shape with rotational symmetry, the axis of rotation AOR may pass through a center of the shape. The point at which the axis of rotation AOR and the rotating chuck 110 meet may be the center of rotation of the rotating chuck 110. However, aspects are not limited thereto, and the upper surface of the rotating chuck 110 may have a rotationally asymmetric shape, and the position at which the axis of rotation AOR passes through the upper surface of the rotating chuck 110 may not be the center of the shape.

The stage 100 including the rotating chuck 110 may be rotated around the predetermined axis of rotation AOR, and the rotation angle φ may represent an angle by which the rotating chuck 110 is rotated around the axis of rotation AOR. If the rotation angle φ is 360°, the substrate S on the rotating chuck 110 may be disposed in a position of substantially overlapping the unrotated substrate S (where φ is 0°). The axis of rotation AOR may be a fixed position relative to the rotating chuck 110, or the axis of rotation AOR may be moved relative to the rotating chuck 110. For example, the axis of rotation AOR may be moved in parallel in one direction, in which the one direction may be a two-dimensional (2D) direction perpendicular to the axis of rotation AOR. Additionally, the axis of rotation AOR may not be parallel to the initial axis of rotation AOR and may be tilted toward a different direction. For example, the stage 100 may further include a tilter 130 that tilts the axis of rotation AOR. The tilter 130 may be disposed inside the stage 100, but aspects are not limited thereto, and the tilter 130 may be connected to the stage 100 as a separate device from the stage 100.

The substrate S may be disposed on the stage 100. The substrate S may include a 3D structure or pattern on one surface. The 3D structure or pattern may be formed on one surface of the substrate S by the lithographic apparatus LA. The substrate S may be an element formed by the lithographic apparatus LA, but aspects are not limited thereto, and it may refer to a general sample that can be analyzed by the analysis apparatus 10. The 3D structure or pattern on the one surface of the substrate S may include a repetitive structure or pattern. However, aspects are not limited thereto, and the 3D structure or pattern on the one surface of the substrate S may include a non-repetitive structure or pattern. Alternatively, the substrate S may include a 2D material on one surface. The substrate S may be disposed such that the surface including the 3D structure or pattern faces an upper portion of the stage 100.

The stage 100 may include a moving chuck 120 disposed on the rotating chuck 110 and capable of translating the substrate S in one direction. The one direction may refer to a two-dimensional direction parallel to the upper surface of the rotating chuck 110 and perpendicular to each other, and the 2D direction may include the first direction and the second direction perpendicular to each other. The moving chuck 120 may move the position of the substrate S such that the axis of rotation AOR passes through a desired region on the substrate S. A specific region on the substrate S may be a region having a 3D structure or pattern of the substrate. At this time, the specific region may be a region irradiated with the light INR by the light source 200. For example, the cross-sectional area of the region irradiated with the light may correspond to 0.5 μm² and 200 μm². While rotating the substrate S around the region irradiated with the light INR using the moving chuck 120, a diffraction pattern corresponding to the rotation angle φ may be collected. The diffraction patterns according to the rotation angles q may have a specific relationship with each other. In the stage 100 of the analysis apparatus 10, the moving chuck 120 is disposed on the rotating chuck 110, but the positional relationship between the rotating chuck 110 and the moving chuck 120 is not limited thereto, and the rotating chuck 110 may be disposed on the moving chuck 120.

According to some implementations, the analysis apparatus 10 may include the light source 200. The light source 200 may irradiate the light INR so that the light INR is incident on the substrate S, and may irradiate the light INR so that the light INR is incident only on a partial region of the upper surface of the substrate S. The light irradiated from the light source 200 may be light with a predetermined wavelength or light with a predetermined wavelength band. For example, if light has a predetermined wavelength, the light may be in a coherent state.

The wavelength of the light INR irradiated from the light source 200 may be selected as needed. For example, wavelengths in the ultraviolet region may be selected, and a wavelength in the deep ultraviolet (DUV) or extreme UV (EUV) region may be selected from among these wavelengths. For example, the general wavelength range of ultraviolet light may be about 10 nm to about 400 nm, the wavelength range of DUV may be about 120 nm to about 200 nm, and the wavelength range of EUV may be about 10 nm to about 120 nm. The light source 200 of the analysis apparatus 10 may irradiate a wavelength of about 13.5 nm. However, aspects are not limited thereto, and the light source 200 may irradiate an X-ray with a wavelength lower than 10 nm (e.g., a wavelength of about 0.01 nm to about 10 nm). For example, the light irradiated from the light source 200 may be X-rays with a wavelength of about 0.1 nm to about 10 nm.

For example, the light source 200 may include a high harmonic generation (HHG) cell HC, a pump laser LAS, a gas supply unit GS, and a power source ES. The light irradiated from the pump laser LAS passes the HHG cell HC, and the light source 200 may eventually irradiate EUV. The gas supply unit GS may provide gas to the HHG cell HC, and the gas may be ionized through the power source ES connected to the HHG cell HC.

The light INR irradiated from the light source 200 may be incident on the substrate S at an angle of incidence θ with respect to the normal direction that is the thickness direction of the substrate S. In this case, the thickness direction of the substrate S may be the Z direction. The placement of the light source 200 may be adjusted such that the angle of incidence θ of the light source 200 has a specific angle. For example, the light source 200 may be disposed such that the angle of incidence θ is about 60° to about 89°. The light INR may be scattered and diffracted by the 3D structure or pattern of the substrate S. The diffracted light DIR may refer to light that is scattered and diffracted by the substrate S and travels in various directions. The diffracted light DIR, and in particular, the light emitted in a direction in which the light INR irradiated from the light source 200 is specularly reflected with respect to a normal line may be referred to as a specular ray SPR. The light source 200 and the sensor 300 may be disposed such that the specular ray SPR may be received by the sensor 300.

According to some implementations, the analysis apparatus 10 may include the sensor 300. The sensor 300 may include a light receiving unit 310 capable of receiving the diffracted light DIR on at least one surface. The light received in the light receiving unit 310 may be sensed together with data including the position where the light is received. The light receiving unit 310 may have a planar structure or a curved surface structure. For example, if the light receiving unit 310 has a planar structure, the light receiving unit 310 may be parallel to a plane formed by the first direction and the second direction perpendicular to the first direction. The first direction may be a direction U, and the second direction may be a direction V.

Since the diffracted light DIR is scattered by the substrate S and travels in various directions, it may form an angle α with the specular ray SPR. For example, it can be said that the angle α of the specular ray SPR itself corresponds to an angle α that is essentially 0. For example, if the light receiving unit 310 of the sensor 300 is disposed to receive the specular ray SPR, then the diffracted light DIR with angles greater than a certain angle may not be sensed by the sensor 300. Meanwhile, since this may be related to the size and shape of the light receiving unit 310 of the sensor 300, the sensible angles may vary depending on the direction in which the light travels. If light with a relatively large angle α is sensed by the sensor 300, the analysis apparatus 10 may have a large numerical aperture (NA) value.

The sensor 300 may include a sensor driving unit that moves the sensor 300 in 3D directions. The sensor driving unit may move the sensor 300 to a position at which the sensor 300 may receive the diffracted light DIR, and also move the sensor 300 so that the specular ray SPR is received. However, aspects are not limited thereto, and the movement of the sensor 300 may be performed through a separate device.

The diffracted light DIR may include a plurality of light components LC, and each of the light components may travel in different directions based on a predetermined diffraction angle φ. The specular ray SPR may be light having the light component LC of the angle α essentially of 0. If the angle of incidence θ of the light INR is relatively small and the diffracted light DIR does not spread over a wide area, that is, if the diffracted light DIR is scattered such that the angle α is small, the light component of the diffracted light DIR that may be received by the sensor 300 may increase. If the angle α of the light component of the diffracted light DIR is large, it may not be received by the light receiving unit 310 of the sensor 300. Alternatively, a light component of the diffracted light DIR may be obscured by the substrate S during scattering, making it undetectable.

In this case, when the light component is obscured by the substrate S, it means that the optical path is disturbed by the substrate S, causing the light component of the diffracted light DIR to be dispersed. For example, the diffracted light DIR may have a cone-shaped spatial distribution due to scattering. In this case, the intensity distribution of the diffracted light DIR in the cone-shaped spatial distribution may vary, and light may not travel to certain part of the spatial distribution depending on the scattering and diffraction phenomena. The certain part of the cone shape may be positioned on a lower side of the upper surface of the substrate S, which may not be a space that can be an actual optical path, and it may represent a portion of the space where the rectilinear propagation of light is physically impeded by the substrate S. For example, when compared to the cone-shaped DIR illustrated in FIG. 2, it can be seen that the diffracted light DIR illustrated in FIG. 3A has a part of the cone shape removed, and the removed region may correspond to a space obscured by the substrate S.

Among the light components of the diffracted light DIR, the light component obscured by the substrate S cannot be sensed by the sensor 300, and accordingly, a diffraction pattern sensed by the sensor 300 may provide a relatively small NA value. If the angle of incidence θ increases or if the angle α of the light component increases, the proportion of the light component of the diffracted light DIR obscured by the substrate S to the light components of the diffracted light DIR may increase relatively.

According to some implementations, the analysis apparatus 10 may rotate the rotating chuck 110 around the axis of rotation AOR, allowing the first region A1 of the substrate S on the rotating chuck 110 to be rotated around the axis of rotation AOR. In this case, the axis of rotation AOR passes through the first region A1 and intersects the first region A1 at the center of rotation COR (see FIG. 4), and the position of the center of rotation COR may remain fixed despite the rotation of the substrate S. The sensor 300 may sense the diffraction patterns corresponding to various rotation angles φ. For example, a first diffraction pattern may be obtained at a rotation angle φ of 0°, a second diffraction pattern at 90°, a third diffraction pattern at 180°, and a fourth diffraction pattern at 270°. Since a portion of the diffracted light DIR, that is, at least one of the plurality of light components is obscured by the substrate S, each diffraction pattern at different rotation angles φ may include a light component LC that is not present in other diffraction patterns. The four angles mentioned above are merely arbitrary and any other angles may also be selected, and fewer or more angles may be selected.

Referring to FIGS. 3A and 3B, for example, the first diffraction pattern may include a first light component LC1 of the diffracted light DIR and a second light component LC2 that travels in a direction different from the first light component LC1, and may not include a third light component LC3 of the diffracted light DIR. The second diffraction pattern may include the third light component LC3 traveling in a direction different from the second light component LC2 of the diffracted light DIR. In this case, the third light component LC3 may be obscured by the substrate S at the first rotation angle, and the first light component LC1 may be obscured by the substrate S at the second rotation angle. Because it is possible to sense the light component LC obscured by the substrate S at a specific rotation angle φ by rotating the rotating chuck 110 and analyzing the first region A1, the analysis apparatus 10 may generate a high-resolution image of the substrate S.

According to some implementations, the analysis apparatus 10 may include the processor 400, and the processor 400 may reconstruct data of the specific region of the substrate S using a plurality of diffraction patterns sensed by the sensor 300. In this case, the plurality of diffraction patterns may be diffraction patterns sensed at different rotation angles φ. The processor 400 may be connected to the sensor 300 to process the diffraction patterns received from the sensor 300. However, aspects are not limited thereto, and the processor 400 may be a component within the sensor 300, or the processor 400 may be included in another electronic device connected to the sensor 300 and may receive data from the sensor 300. The processor 400 may use various reconstruction methods to reconstruct the diffraction patterns into data of the specific region of the substrate S. For example, the plurality of diffraction patterns obtained by the light source 200 irradiating the first region A1 may image the 3D structure or pattern of the first region A1. For example, the reconfiguration method of the processor 400 may be a method using phase retrieval. By performing phase retrieval and reconstruction of the plurality of diffraction patterns corresponding to various rotation angles φ for the first region A1 through which the axis of rotation passes, it is possible to improve the resolution of the image of the 3D structure or pattern of the first region A1. This is because the light component LC of the diffracted light DIR that is obscured by the substrate S at one rotation angle φ can be sensed by the sensor 300 at other rotation angles φ, such that the obscured light components LC can be reflected in reconstructing the overall diffraction pattern and data of the first region A1.

In addition, it is also possible to reconstruct data for a plurality of different regions and the entire region including the different regions. For example, the diffraction patterns of a plurality of regions may be sensed individually, and then the 3D structure or pattern of the plurality of regions and the entire region including the plurality of regions may be imaged using ptychography method. In the ptychography method, one of the plurality of regions may partially overlap at least one of the other regions.

FIG. 4 illustrates positions of the substrate S on the stage 100 at the rotation angles φ of 0°, 30°, 60°, and 90°, respectively, and data obtained by measuring diffraction patterns of the first region A1 irradiated with the light INR. The center of rotation COR of the first region A1 may remain substantially fixed even as the substrate S is rotated. The light component of the diffracted light DIR may be defined by a direction of propagation based on a predetermined rotation angle φ, and if the rotation angle φ changes, the light component may be rotated in the U-V plane with the specular ray SPR as a reference point. The diffracted light DIR sensed at the rotation angle of 0° and the diffracted light DIR sensed at the rotation angle of 30° may include an overlapping light component LC. The overlapping light component LC of the diffracted lights DIR sensed at rotation angles 0° and 30° may be sensed at different points of the light receiving unit 310 of the sensor 300, and these different points may be positioned on concentric circles from the point where the specular ray SPR is sensed. In addition, the light component LC of the diffracted light DIR sensed at the rotation angle of 30° may include the light component LC obscured by the substrate S at the rotation angle of 0°. In some aspects, the rotation angles φ may not be limited to the above values and any other two rotation angles φ may also be applied.

Referring to FIG. 5A, an optical limit of resolution OLR and the light receiving region RC of the sensor 300 are shown. In this graph, X-axis may represent a spatial frequency in the direction X, and Y-axis may represent a spatial frequency in the direction Y, and the unit of the spatial frequency may be mm⁻¹ or m⁻¹. The diffracted light DIR may be represented over a predetermined spatial frequency domain in the graph. The light components LC of the diffracted light DIR may be represented as vectors according to the spatial frequencies of the light components LC. The optical limit of resolution OLR of the sensor 300 may represent the range of spatial frequencies of light that can be sensed by the analysis apparatus when the ideal numerical aperture NA is 1. The light receiving region RC may represent the range of spatial frequencies of light that the sensor can sense, and the light receiving region RC may correspond to the NA of the apparatus. If the vector endpoint of the light component LC is located inside or on the boundary of the light receiving region RC, the sensor 300 may sense the corresponding light component LC. If the vector endpoint of the light component LC is positioned outside the light receiving region RC, the sensor 300 cannot sense the corresponding light component LC. For example, the first light component LC1 and the second light component LC2 may be included inside the light receiving region RC and thus can be sensed, but the third light component LC3 and a fourth light component LC4 may be positioned outside the light receiving region RC and thus cannot be sensed. In other words, only the portion where the region including the entire light components of the diffracted light DIR overlaps with the light receiving region RC may be sensed by the light receiving region RC. The size of the light receiving region RC increase in proportion to the size of the light receiving unit 310 of the sensor 300. Meanwhile, since the cross-sectional shape of the light receiving region of the light receiving unit 310 in the U-V cross section is transformed to be displayed on a graph with kₓ and k_{y} axes, the shape of the light receiving region RC may be different from that of the light receiving unit 310.

Referring to FIG. 5B, it can be seen that the first to fourth light components LC1, LC2, LC3, and LC4 of the diffracted light DIR change according to the rotation angles φ. As the rotation angle φ is rotated from 0° to 90°, the light components LC of the diffracted light DIR represented on the graph may be rotated 90° clockwise around the specular ray SPR. Likewise, as the rotation angle φ is rotated from 0° to n° (where 0<n<360), the light components LC of the diffracted light DIR represented on the graph may be rotated n° counterclockwise around the light components LC of the specular ray SPR. If the rotating chuck 110 is rotated in the opposite direction to the initial direction of rotation, the light components LC of the diffracted light DIR may be rotated clockwise on the graph. As the rotating chuck 110 is rotated, whether the light components LC of the diffracted light DIR are located inside the light receiving region RC may change. For example, at the rotation angle φ of 0°, the first and second light components LC1 and LC2 may be positioned inside the light receiving region RC. At the rotation angle φ of 90°, the second and third light components LC2 and LC3 may be positioned inside the light receiving region RC. At the rotation angle φ of 180°, the fourth light component LC4 may be positioned inside the light receiving region RC. At the rotation angle φ of 270°, the first, second, and fourth light components LC1, LC2, and LC4 may be positioned inside the light receiving region RC. Since two of the diffraction patterns obtained at each rotation angle φ may include different light components LC, combining the diffraction patterns and using the result for data configuration may allow a fine analysis of the three-dimensional structure or pattern. Referring to FIG. 5C, it can be seen that the light receiving region RC is expanded by rotation. The light receiving regions RC in FIG. 5C are expanded regions at the rotation angles φ of 0°, 90°, 180°, and 270°. If the diffracted light DIR is sensed at a plurality of other rotation angles φ, then the size and area of the light receiving region RC may be changed. For example, the light receiving region RC may be expanded wider if the interval between the rotation angles φ decreases.

In some aspects, the light source 200 of the analysis apparatus 10 may be disposed such that the angle of incidence θ is between 75° to 89° in a region of the substrate S irradiated with the light INR. The expanded light receiving region RC provided by the analysis apparatus 10 may offer greater advantages as the angle of incidence θ of the light INR increases. In general, for samples used in semiconductor devices (e.g., SiO₂, Ge, Si₃N₄, Si, etc.), if the angle of incidence θ is not large enough, the reflectance may be low and the signal intensity of the diffracted light DIR sensed by the sensor 300 may be too low. If sensed signal intensity is low, it may be difficult to analyze and image the 3D structure or pattern of the sample. For example, for 13 nm samples of SiO₂, Ge, Si, or Si₃N₄, if the angle of incidence θ is equal to or less than 75°, the reflectance for each sample may be lower than about 0.1. If the angle of incidence θ is increased to increase the reflectance, the angle formed by the specular ray SPR with the normal line may also be increased. In this case, the range of diffracted light DIR obscured by the sample may increase, and the range of diffracted light DIR sensed by the sensor 300 may decrease. Thus, the ability of the analysis apparatus 10 to image the 3D structure or pattern of the sample may decrease. In other words, increasing the reflectance of the sample may decrease the resolution of the apparatus. This can be complemented by rotating and analyzing a region of the sample through the analysis apparatus 10. The analysis apparatus 10 may have a small decrease in resolution or substantially maintain the resolution even if the reflectance of the sample increases. Accordingly, the analysis apparatus with high optical signal intensity and high resolution may be provided.

For example, the magnitude of the reflected signal of diffracted light DIR in the EUV wavelength band may be at least twice as high as in the case of no rotation, and it may be at least six times higher if the angle of incidence is properly selected. The above description is not limited to the samples used in semiconductor devices such as SiO₂, Ge, Si or Si₃N₄, and the aspects of the disclosure may be used in various other samples, or samples in technical fields other than semiconductors. In addition, the aspects described above may be used for samples showing sufficient reflectance only at a high reflection angle. Furthermore, the analysis apparatus 10 may be applied at high angle of incidence θ and may provide high-resolution imaging analysis even when the light source 200 irradiates X-rays.

In addition, according to one or more implementations, the analysis apparatus 10 may achieve non-destructive high-resolution imaging of the 3D structure or pattern of the substrate S without applying physical or chemical modifications to the sample. For example, using the EUV wavelength band, it is possible to lower the transmittance to the sample and thus reduce interference due to the inside of the sample, and by applying a high angle of incidence θ, it is possible to increase the magnitude of the signal of the diffracted light DIR, thereby achieving non-destructive high-resolution imaging.

In some aspects, the analysis apparatus 10 may analyze the physical, chemical, electromagnetic, optical, crystallographic characteristics, etc. of a region or the entire region of the substrate S. For example, the imaging the entire region of the 3D structure or pattern of the substrate S may be the result of analyzing the physical characteristics of the substrate S.

The analysis apparatus 10 may further include a pumping element 500. The pumping element 500 may project pump light onto a region of the substrate S to excite electrons in the region, and with the electrons excited, may analyze the substrate S and analyze the physical, chemical, electromagnetic, optical, or crystallographic characteristics of the substrate S. The pumping element 500 may be optically connected to the light source 200. For example, the light irradiated from the pumping element 500 may originate from the pump laser LAS of the light source 200. The light irradiated from the pumping element 500 may have the same wavelength as or different wavelength from the light irradiated from the light source 200. The light irradiated from the light source 200 and the light irradiated from the pumping element 500 may be coherent with each other. The analysis apparatus 10 may be used not only for the analysis of the 3D structure or pattern of typical samples, but also for the analysis of various other materials including 2D materials, magnetic materials, etc.

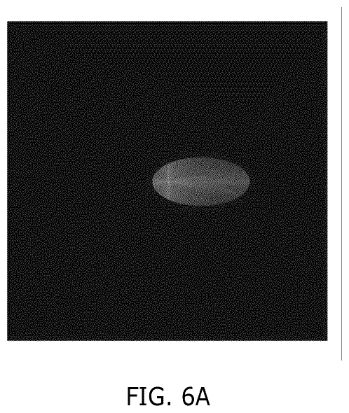

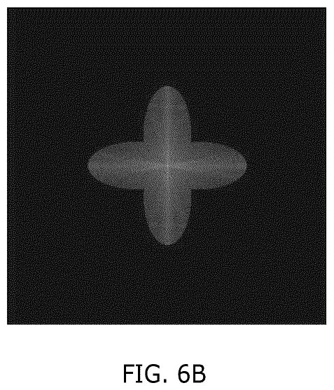

FIG. 6A shows a simulation result of sensing a diffraction pattern of a region of a fixed substrate that is not rotated, and FIG. 6B shows a simulation result showing a resultant diffraction pattern obtained by synthesis and reconstruction from diffraction patterns corresponding to a plurality of angles obtained while rotating a region of the substrate.

Referring to FIG. 6A, only a portion of the diffraction pattern by the total diffracted light DIR may be sensed, and the size of the sensed diffraction pattern region may be proportional to the NA value of the apparatus. The simulation result illustrated in FIG. 6B is obtained by the synthesis and reconstruction from diffraction patterns corresponding to a plurality of rotation angles φ obtained while rotating a region of the substrate S, in which a wider region may be sensed compared to the diffraction pattern (see FIG. 6A) obtained when the rotation angle φ is fixed. In this case, the NA value of the apparatus may be further increased. The simulation result in FIG. 6B is obtained at the rotation angles φ of 0°, 90°, 180°, and 270°, but this is only one example, and other rotation angles φ may be selected, or fewer or more rotation angles φ may be selected. The rotation angle φ may be selected to achieve the desired NA value, and as the NA value increases, high-resolution imaging may be obtained. For example, by rotating and reconstructing diffraction patterns corresponding to the plurality of rotation angles φ, it is possible to increase the resolution by about 1.2 and 2 times compared to the diffraction pattern obtained without rotation. Alternatively, higher resolution may be achieved depending on the configuration of the analysis apparatus.

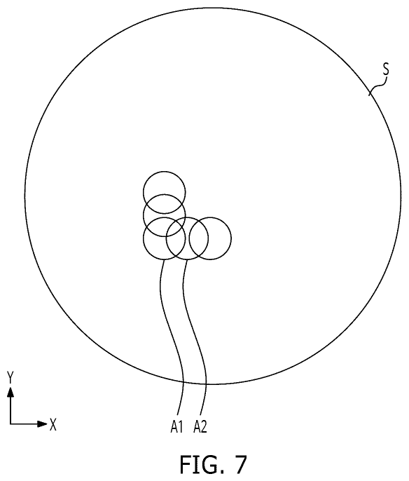

FIG. 7 is a conceptual diagram illustrating several regions on the substrate where light is irradiated.

Referring to FIG. 7, the light INR emitted from the light source may be irradiated onto the first region A1 of the substrate S. The first region A1 may have various shapes depending on the light. For example, the first region A1 may have shapes such as circles, ellipses, etc. However, aspects are not limited thereto, and the first region A1 may have different shapes according to beam profiles. The moving chuck 120 may be used such that the light INR may be irradiated onto a region, e.g., onto a second region A2 partially overlapping with the first region A1. As a result, the axis of rotation AOR may pass through the second region A2. For example, the second region A2 may have a relationship of parallel translation with the first region A1 in the X-Y plane. For example, the plurality of regions may be disposed in M rows (where, M is a natural number greater than or equal to 2) and N columns (where, N is a natural number greater than or equal to 2) along the X-Y plane.

As one of the methods of sensing diffracted light DIR and reconstructing it into data, ptychography may be used. Ptychography is a technique capable of imaging all of a plurality of regions partially overlapping with each other using a plurality of diffraction patterns obtained from the plurality of regions. In the ptychography, some of the plurality of regions set on the substrate may be spaced apart by a constant distance in one direction. A distance between one region and another region closest thereto may have a constant distance. With the ptychography, it is possible to image the 3D structure or pattern of at least one region or the entire region of the substrate.

When irradiating the light INR onto the plurality of regions, the order of the parallel translation of the substrate and the rotation of the substrate may be selected as needed. According to one aspect, diffraction patterns for each of M×N regions may be sensed at one rotation angle φ. The substrate S may be rotated to another rotation angle φ around the axis of rotation AOR passing through the center of the substrate S, while the diffraction patterns for each of the M×N regions are sensed, and this process may be repeated by changing the rotation angle q. In this case, the change in the relative positions of the regions on the rotating chuck 110 may be considered in the processor 400 during the reconstruction operation. For example, the diffraction patterns corresponding to the first rotation angle among the M×N regions of the substrate S may be sensed by the sensor 300, and the diffraction pattern corresponding to the second rotation angle may be sensed by the sensor 300. The processor 400 may map the M×N diffraction patterns corresponding to the first rotation angle to reconstruct them into first sub-data. The first sub-data may be an image of 3D structure or pattern of the substrate S obtained at the first rotation angle. Likewise, the M×N diffraction patterns corresponding to the second rotation angle may be mapped and reconstructed into second sub-data, and the second sub-data may be an image of 3D structure or pattern of the substrate S obtained at the second rotation angle. The first sub-data and the second sub-data may be mapped by the processor 400 and reconstructed into combined data with a higher resolution.

According to another implementation, diffraction patterns corresponding to each rotation angle φ of one region of the M×N regions may be sensed while changing the rotation angle φ around the axis of rotation AOR passing through the one region. The position of the substrate may be parallel translated to sense the diffraction patterns respectively corresponding to the rotation angles φ of other regions, and this process may be repeated for each of the M×N regions.

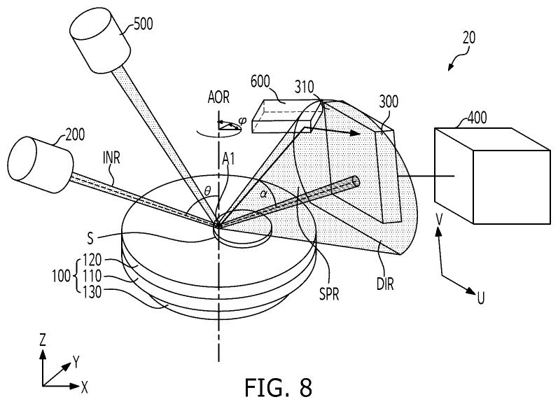

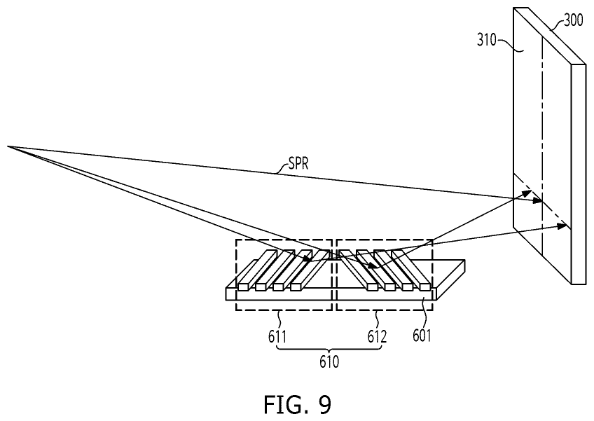

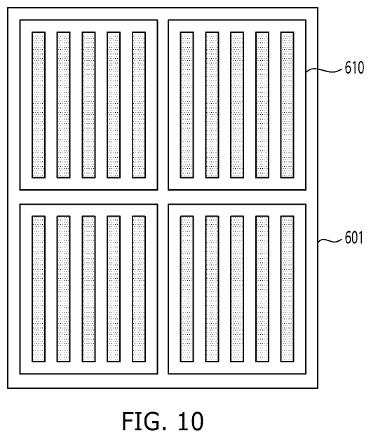

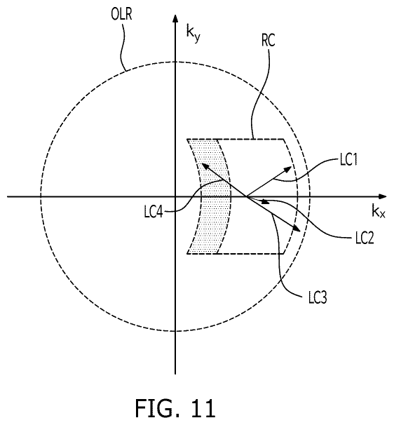

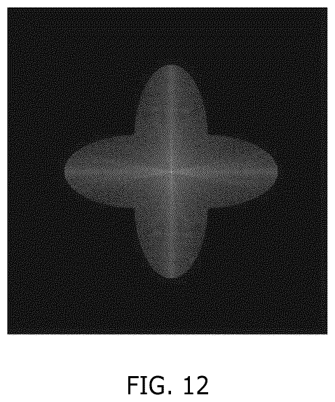

FIG. 8 is a diagram illustrating an analysis apparatus according to one or more implementations, FIG. 9 is a conceptual diagram illustrating a sensor and an optical element included in the analysis apparatus according to one or more implementations, and FIG. 10 is diagram illustrating a diffraction pattern disposed on the optical element. FIG. 11 is a graph illustrating a light receiving region that can be obtained when the analysis apparatus includes the optical element according to one or more implementations, and FIG. 12 shows a simulation result showing a diffraction pattern sensed when the analysis apparatus includes the optical element according to one or more implementations.

In the description of an analysis apparatus 20 according to one or more implementations in FIG. 8, any duplicate description with the analysis apparatus 10 in FIG. 2 will be omitted.

According to FIG. 8, the analysis apparatus 20 according to one or more implementations may include at least one optical element 600 that steers a portion of the diffracted light DIR toward the sensor 300. The optical element 600 of the analysis apparatus 20 may steer the portion of the diffracted light DIR toward the sensor 300, which can enhance the resolution of the analysis apparatus 20. The portion of the diffracted light DIR mentioned above may include light components that cannot be sensed in the light receiving region CD of the sensor 300 in the absence of the optical element 600.

According to some implementations, the analysis apparatus 20 may include at least one optical element 600, and the diffracted light DIR may be incident on the optical element 600. The optical element 600 may be located in the spatial distribution of the diffracted light DIR, i.e., in the optical path of the diffracted light DIR. For example, the optical element 600 may be disposed on the optical path of the diffracted light DIR between the stage 100 and the sensor 300. The optical element 600 may be disposed so as not to block some of the light components LC of the diffracted light DIR that directly travel towards the sensor 300. Among the plurality of light components included in the diffracted light DIR, the optical element 600 may steer the light components with large angles α. The diffracted light DIR may be incident on the optical element 600 and steered to a direction different from its initial path, and the direction to which the diffracted light is steered may be a direction to be incident on the light receiving unit 310 of the sensor 300. In addition, the direction to which the light is steered may be a direction toward a region different from the region in which the specular ray SPR is sensed in the light receiving unit 310 of the sensor 300. For example, if there is no optical element 600, the direction to which light is steered may be a direction that would head toward a region in which light is not sensed in the light receiving unit 310 of the sensor 300. Thus, if there is no optical element 600 and light is received in the region in which light is not sensed, the interference effect caused by the diffracted light DIR that is sensed directly without passing through the optical element 600 may be reduced. However, aspects are not limited thereto, and the direction to which the light is steered may be a direction heading toward a region in which the light is sensed, but the sensed signal intensity is low due to the small intensity of light. Using the optical element 600, the analysis apparatus 20 may sense the diffracted light DIR over a wider range without moving the sensor 300.

For example, the optical element 600 may include a mirror with a flat or curved reflecting surface. The mirror may include a first pattern and a second pattern, and a direction perpendicular to a reflective surface of the first pattern may differ from a direction perpendicular to a reflective surface of the second pattern. In this case, the light steering directions by the first pattern and the second pattern may be different from each other.

Alternatively, for example, the optical element 600 may include a diffraction grating 601, and the diffraction grating 601 may include a plurality of grating patterns extending in one direction. The plurality of grating patterns may be arranged to extend in two directions perpendicular to each other, and the two extending directions are directions perpendicular to a thickness direction of the diffraction grating 601. Each of the plurality of grating patterns may have different light steering directions according to the arrangement of grating of the grating patterns. If light of substantially the same angle of incidence is incident on two grating patterns having substantially the same arrangement of grating, the directions of light steering by the two grating patterns may be substantially the same.

Referring to FIG. 9, the directions of light steering by a first grating pattern 611 and a second grating pattern 612 may differ from each other. The light steered by the first grating pattern 611 may be received at a position different from a position at which the specular ray SPR is received in the light receiving unit 310. The light steered by the second grating pattern 612 may be received at a position different from a position at which the light steered by the first grating pattern 611 is received. A plurality of grating patterns 610 may be disposed such that the direction of light steering is different for each position at which the diffracted light DIR is incident on the diffraction grating 601.

Referring to FIG. 10, if the plurality of grating patterns 610 included in the diffraction grating 601 are arranged in one direction, the light may be steered to the first direction. If the plurality of grating patterns 610 are additionally arranged in another direction perpendicular to the one direction, the light may be steered to the first direction and the second direction. In this case, the first and second directions may be perpendicular to each other. For example, the first and second directions may be perpendicular to the thickness direction of the optical element 600 on which the grating patterns are disposed.

Referring to FIG. 11, the analysis apparatus 20 according to one or more implementations may have a light receiving region RC expanded by the optical element 600. For example, if the position of the optical element 600 orthogonally projected onto the U-V plane is on the V-axis (see FIG. 8), the light receiving region RC represented on the graph may be extended and expanded parallel to the kₓ direction.

The above arrangement may have the pattern described above, and if the arrangement of the light source 200, sensor 300, and optical element 600 changes, then the light receiving region RC may be expanded in different patterns. Since the NA value increases with the expanded light receiving region RC, a high-resolution image may be obtained. Referring to FIG. 12, it can be seen that the region of the sensed diffraction pattern is expanded compared to FIG. 6B. For example, by including the sensor 300 that senses diffraction patterns corresponding to a plurality of diffraction angles φ while the rotating chuck 110 is rotated, and the optical element 600 that steers light, light components with large angles α may be measured. For example, a light component with a sin α value of about 0.6 may be measured.

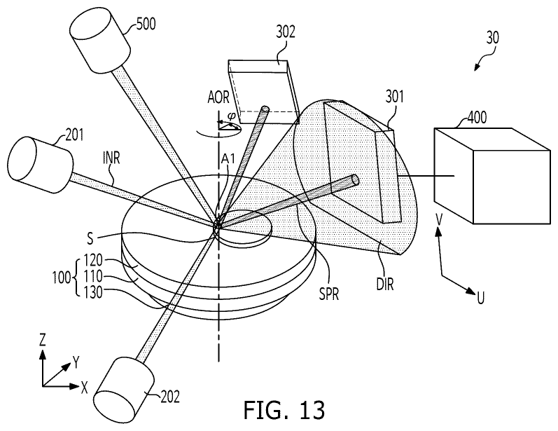

FIG. 13 is a perspective view of an analysis apparatus according to one or more implementations.

In the description of an analysis apparatus 30 according to one or more implementations in FIG. 13, any duplicate description with the analysis apparatus 10 in FIG. 2 will be omitted.

Referring to FIG. 13, the analysis apparatus 30 according to one or more implementations may include at least one light source 200 which includes a first light source 201 and a second light source 202, and at least one sensor 300 which includes a first sensor 301 and a second sensor 302.

The first light source 201 may be disposed on a circumference of a virtual circle centered on the axis of rotation AOR and having a cross-section perpendicular to the axis of rotation. The second light source 202 may also be disposed on the circumference of the above virtual circle, in which case respective distances from the center of the virtual circle on the axis of rotation AOR to the first light source 201 and the second light source 202 are substantially equal to each other. In other words, the first light source 201 and the second light source 202 may be disposed on concentric circles centered on the axis of rotation AOR and having cross-sections perpendicular to the axis of rotation AOR. The first and second light sources 201 and 202 may be disposed apart from each other. If the center of the virtual circle is a vertex, the first and second light sources 201 and 202 may be disposed to have a certain angle with respect to the vertex. The certain angle may be selected as needed, and the analysis apparatus 30 may further include a configuration to adjust the certain angle. For example, the certain angle may be 30°, 60°, 90°, etc. However, aspects are not limited thereto, and the first light source 201 and the second light source 202 may be disposed in contact with each other, in which case the directions of the light irradiated from the first light source 201 and of the light irradiated from the second light source 202 may be different from each other.

Alternatively, the light source 200 may be disposed to extend along (or in the direction of) an arc of the virtual circle centered on the axis of rotation AOR and having a cross-section perpendicular to the axis of rotation AOR. That is, the light source 200 may be disposed over a predetermined angular range. In this case, the light source 200 may irradiate light to a region on the substrate S over a predetermined angular range along the axis of rotation AOR. In this case, a plurality of angles within the predetermined angular range may have discrete values or continuous values.

The first and second light sources 201 and 202 may irradiate light generated by the same pump laser LAS. In this case, the lights irradiated from the first and second light sources 201 and 202 may be coherent with each other.

Although not separately illustrated in FIG. 13, the light irradiated from the second light source 202 is also scattered in the first region A1 to form diffracted light.

The first sensor 301 may be disposed on the circumference of the virtual circle centered on the axis of rotation AOR and having a cross-section perpendicular to the axis of rotation, and the second sensor 302 may also be disposed on the circumference of the virtual circle, in which case the distances from the center of the virtual circle on the axis of rotation to the first sensor 301 and the second sensor 302 may be substantially equal to each other. In other words, the first sensor 301 and the second sensor 302 may be disposed on concentric circles centered on the axis of rotation and having cross-sections perpendicular to the axis of rotation AOR. The first and second sensors 301 and 302 may be disposed apart from each other. If the center of the virtual circle is a vertex, the first and second sensors 301 and 302 may be disposed to have a certain angle with respect to the vertex. The certain angle may be selected as needed, and the analysis apparatus 30 may further include a configuration to adjust the certain angle. For example, the certain angle may be 30°, 60°, 90°, etc. The certain angles that the first and second sensors 301 and 302 subtend may be selected to match the certain angles that the first and second light sources 201 and 202 subtend. A first concentric circle including the first and second light sources 201 and 202 in its radius and a second concentric circle including the first and second sensors 301 and 302 in its radius may have the same radius or different radii. In addition, the plane including the first concentric circle and the plane including the second concentric circle may be the same plane or planes in a parallel relationship with each other.

However, aspects are not limited thereto, and the first sensor 301 and the second sensor 302 may be disposed in contact with each other, in which case the direction of specular ray from the first diffracted light irradiated and scattered from the first light source 201 and the direction of specular ray from the second diffracted light irradiated and scattered from the second light source 202 may differ from each other.

Alternatively, the sensor 300 may be disposed to extend along (or in the direction of) an arc of a virtual circle centered on the axis of rotation AOR and having a cross-section perpendicular to the axis of rotation AOR. That is, the sensor 300 may be disposed over a predetermined angular range. In this case, the sensor 300 may sense the diffracted light over the angular range around the axis of rotation AOR. In this case, a plurality of angles within the predetermined angular range may have discrete values or continuous values.

The first and second sensors 301 and 302 may be connected to the same processor 400, and the diffraction patterns respectively sensed by the first and second sensors 301 and 302 may be processed in the same processor 400 and used together for the data reconstruction.

The positional relationship between the first light source 201 and the first sensor 301 and the positional relationship between the second light source 202 and the second sensor 302 may be rotationally symmetric with respect to the axis of rotation AOR. For example, a first straight line connecting the first light source 201 and the first sensor 301 and a second straight line connecting the second light source 202 and the second sensor 302 may be rotationally symmetric with respect to the axis of rotation AOR. That is, the first straight line rotated by the certain angle may overlap with the second straight line. For example, if the position of the first light source 201 is rotated by the certain angle with respect to the axis of rotation AOR, the position of the first light source 201 may be substantially the same as the position of the second light source 202 before the rotation, and if the position of the first sensor 301 is rotated by the certain angle with respect to the axis of rotation AOR, the position of the first sensor 301 may be substantially the same as the position of the second sensor 302 before rotation.

The at least one light source 200 and the at least one sensor 300 are not limited to certain aspects described above, and three or more light sources and the same number of sensors corresponding thereto may be provided. In this case, the angular intervals between the light sources 200 may be constant or different from each other.

The analysis apparatus 30 according to one or more implementations may include two or more light sources 200 and two or more sensors 300 to simultaneously or sequentially sense diffraction patterns corresponding to two or more angles. Accordingly, the speed at which the analysis apparatus 30 measures the physical, electromagnetic, chemical, optical, or crystal structural characteristics of the substrate S may be improved. For example, the speed of imaging the three-dimensional structure or pattern of the substrate S with high resolution can be improved, and measurement errors can be reduced by reducing the movement of the substrate.

In addition, the at least one optical element may include a first optical element and a second optical element, and the first optical element and the second optical element may be arranged in a manner similar to the arrangement of the first and second light source 201 and 202 or the arrangement of the first sensor and second sensor 301 and 302 described above, and a detailed description thereof will be omitted.

The positional relationship between the first light source 201, the first sensor 301, and the first optical element and the positional relationship between the second light source 202, the second sensor 302, and the second optical element may be rotationally symmetric with respect to the axis of rotation AOR. For example, a first plane including the first light source 201, the first sensor 301, and the first optical element and a second plane including the second light source 202, the second sensor 302, and the second optical element may be rotationally symmetric with respect to the axis of rotation AOR. That is, the first plane rotated by the certain angle may overlap with the second plane. For example, if the position of the first light source 201 is rotated by the certain angle with respect to the axis of rotation AOR, the position of the first light source 201 may be substantially the same as the position of the second light source 202 before the rotation, and if the position of the first sensor 301 is rotated by the certain angle with respect to the axis of rotation AOR, the position of the first sensor 301 may be substantially the same as the position of the second sensor 302 before rotation, and if the position of the first optical element is rotated by the certain angle with respect to the axis of rotation AOR, the position of the first optical element may be substantially the same as the position of the second optical element before rotation.

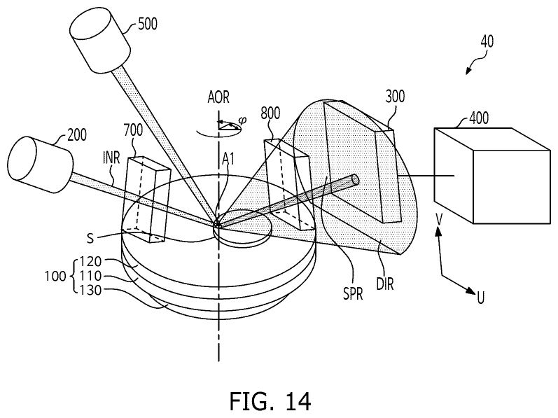

FIG. 14 is a perspective view of an analysis apparatus according to one or more implementations.

In the description of an analysis apparatus 40 according to one or more implementations in FIG. 14, any duplicate description with the analysis apparatus 10 in FIG. 2 will be omitted.

Referring to FIG. 14, the analysis apparatus 40 according to one or more implementations may include a first optical system 700 through which the light INR emitted from the light source 200 may be passed and irradiated onto a region of the substrate S, and a second optical system 800 through which diffracted light DIR scattered in one region may be passed.

Some or substantially all of the light INR irradiated from the light source 200 may pass through the first optical system 700. For example, the first optical system 700 may be an optical filter that passes only the light that has a specific value or a specific range of values for at least one controllable characteristic. For example, the first optical system 700 may be an optical filter that transmits only the light that has a predetermined wavelength value or a predetermined wavelength band. Alternatively, it may be a polarization filter that transmits only the light that has a predetermined polarization direction component. For example, the first optical system 700 may be an interferometer for time resolution of the light INR. The time-resolved light through the interferometer may be sensed by the sensor 300 at predetermined time intervals.

Some or substantially all of the diffracted light DIR may pass through the second optical system 800 before being sensed by the sensor 300. For example, the second optical system 800 may be an optical filter that passes only the light that has a specific value or a specific range of values for at least one controllable characteristic. For example, the first optical system 700 may be an optical filter that transmits only the light that has a predetermined wavelength value or a predetermined wavelength band. Alternatively, it may be a polarization filter that transmits only the light that has a predetermined polarization direction component.

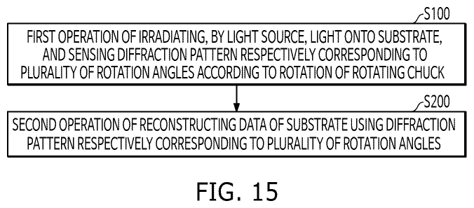

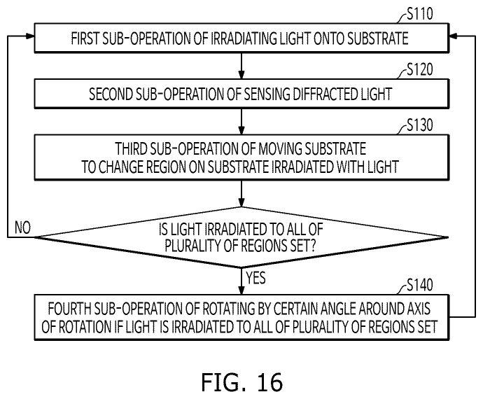

FIG. 15 is a flowchart provided to explain an analysis method according to one or more implementations, and FIG. 16 is a flowchart provided to explain sub-operations of a first operation of the analysis method.

Referring to FIG. 15, the 3D structure or pattern of one surface of the substrate S may be imaged using the analysis apparatus 10, 20, 30, and 40 according to one or more implementations. The substrate S may be disposed such that the axis of rotation AOR passes through a region of the substrate S. The analysis method may include a first operation S100 of irradiating, by the light source 200, light onto a plurality of regions including a first region of the substrate S, and sensing a diffraction pattern of a diffracted light DIR formed by scattering from the first region, for each of a plurality of rotation angle φ according to a rotation of the rotating chuck, and a second operation S200 of reconstructing data of the first region by using the diffraction pattern corresponding to each of the plurality of rotation angle φ. For example, the surface of the substrate S may include M×N regions (where, M or N is a natural number of 1 or more), and these M×N regions may be positioned to extend along the X and Y axes. One of the M×N regions may partially overlap with at least one of the other regions. According to FIG. 16, in order to irradiate each of the M×N regions with the light INR, the first operation S100 includes a first sub-operation S110 of irradiating the light INR onto the substrate S, a second sub-operation S120 of sensing the diffracted light DIR, a third sub-operation S130 of translating the substrate S to change the region on the substrate irradiated with the light INR, and a fourth sub-operation S140 of rotating by a certain rotation angle φ around the axis of rotation AOR if the light INR is irradiated to all M×N regions. The first to fourth sub-operations S110, S120, S130, and S140 may be repeated. It is described that the analysis method performs the rotating operation after completing all the X-Y movement operations, but aspects are not limited thereto, and the X-Y movement operations may be performed after all the rotating operations are performed for one region.

The analysis apparatus 10, 20, 30, and 40 described with reference to FIGS. 1 and 14 may be an independent analysis apparatus or component included in an electronic device. For example, the electronic device may be a lithographic apparatus LA, and the 3D pattern or structure of the apparatus may be imaged by the analysis apparatus during or after the 3D structure or pattern of the element is formed by the lithographic apparatus LA.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. An analysis apparatus, comprising:
a stage including a rotating chuck configured to be rotated around an axis of rotation;
one or more light sources configured to irradiate light onto a first region of a substrate disposed on the stage;
one or more sensors configured to sense diffraction patterns that are respectively correspond to a plurality of rotation angles based on a rotation of the rotating chuck, the diffraction patterns being generated based on scattering of the light irradiated onto the first region of the substrate; and
a processor configured to reconstruct data of the first region using the diffraction patterns.

2. The analysis apparatus of claim 1, wherein the axis of rotation passes through the first region of the substrate.

3. The analysis apparatus of claim 1, wherein the stage further comprises a moving chuck configured to translate the substrate in a direction perpendicular to the axis of rotation, and
wherein the moving chuck is configured to move the substrate such that the axis of rotation passes through a second region that partially overlaps with the first region.

4. The analysis apparatus of claim 3, wherein the processor is configured to match the diffraction patterns corresponding to each of the plurality of rotation angles of the first region and the second region to reconstruct data of an overlapped region included in both the first region and the second region.

5. The analysis apparatus of claim 3, wherein the moving chuck is disposed on the rotating chuck.

6. The analysis apparatus of claim 3, wherein the processor is configured to:
map a first diffraction pattern corresponding to a first rotation angle of a plurality of regions on the substrate to reconstruct first sub-data,
map a second diffraction pattern corresponding to a second rotation angle different from the first rotation angle of the plurality of regions on the substrate to reconstruct second sub-data, and
map the first sub-data and the second sub-data to reconstruct data.

7. The analysis apparatus of claim 1, wherein at least one of the one or more light sources is configured to irradiate an extreme ultraviolet light.

8. The analysis apparatus of claim 1, wherein at least one of the one or more light sources is configured to irradiate the light onto the first region of the substrate with an incident angle from 75 to 89 degrees.

9. The analysis apparatus of claim 1, further comprising a tilter configured to tilt the axis of rotation.

10. The analysis apparatus of claim 1, further comprising a pumping element configured to optically couple to at least one of the one or more light sources and to project light into the first region to excite the first region.

11. The analysis apparatus of claim 1, wherein
the one or more light sources comprise a first light source and a second light source that are configured to irradiate coherent light,
the one or more sensors comprise a first sensor and a second sensor,
the first light source and the second light source are disposed equidistant from the axis of rotation and subtend an angle relative to the axis of rotation, and
the first sensor and the second sensor are disposed equidistant from the axis of rotation and subtend the angle relative to the axis of rotation.

12. The analysis apparatus of claim 1, further comprising an optical system positioned in an optical path of the light from at least one of the one or more light sources onto the first region of the substrate, wherein the optical system comprises at least one of an optical filter, a polarization filter, or an interferometer.

13. The analysis apparatus of claim 1, wherein at least one of the one or more sensors is configured to move in at least one of three-dimensional directions.

14. An analysis apparatus, comprising:
a stage including a rotating chuck configured to be rotated around an axis of rotation;
one or more light sources configured to irradiate light onto a first region of a substrate disposed on the stage;
one or more sensors configured to sense diffraction patterns that respectively correspond to a plurality of rotation angles based on a rotation of the rotating chuck, the diffraction patterns being generated based on scattering of the light irradiated onto the first region of the substrate;
one or more optical elements configured to steer a portion of a diffracted light scattered from the first region toward the one or more sensors; and
a processor configured to reconstruct data of the first region using the diffraction patterns.

15. The analysis apparatus of claim 14, wherein at least one of the one or more optical elements comprises one or more diffraction gratings or one or more mirrors.

16. The analysis apparatus of claim 15, wherein
the one or more optical elements comprise a mirror,
the mirror comprises a first pattern and a second pattern, and
a direction perpendicular to a reflective surface of the first pattern and a direction perpendicular to a reflective surface of the second pattern are different from each other.

17. The analysis apparatus of claim 15, wherein
the one or more optical elements comprise a diffraction grating,
the diffraction grating comprises a first grating pattern and a second grating pattern, and
the first grating pattern and the second grating pattern have different grating arrangements.

18. The analysis apparatus of claim 15, wherein
the one or more optical elements comprise a diffraction grating having a plurality of grating patterns, and
the plurality of grating patterns are arranged in one direction.

19. The analysis apparatus of claim 15, wherein
the one or more optical elements comprise a diffraction grating having a plurality of grating patterns, and
the plurality of grating patterns are arranged in two directions perpendicular to each other.

20. An analysis apparatus comprising:
a stage that includes a rotating chuck configured to be rotated around an axis of rotation and a moving chuck configured to translate a substrate disposed on the rotating chuck in a direction perpendicular to the axis of rotation;
one or more light sources configured to irradiate light onto a first region of the substrate;
one or more sensors configured to sense diffraction patterns that respectively correspond to a plurality of rotation angles based on a rotation of the rotating chuck, the diffraction patterns being generated based on scattering of the light irradiated onto the first region of the substrate;
one or more diffraction gratings configured to steer at least one portion of a diffracted light scattered from the first region toward the one or more sensors; and
a processor configured to reconstruct data of the first region using the diffraction patterns, wherein
the one or more diffraction gratings comprise a first grating pattern configured to steer a first portion of the at least one portion of the diffracted light to a first direction and a second grating pattern configured to steer a second portion of the at least one portion of the diffracted light to a second direction different from the first direction, and
the first portion of the at least one portion of the diffracted light steered at the first grating pattern and the second portion of the at least one portion of the diffracted light steered at the second grating pattern are received at different positions of at least one of the one or more sensors.
